(19) United States
(12) Patent Application Publication
(10) Pub. No.: US 2024/0021772 A1
(43) Pub. Date: Jan. 18, 2024

(54) OPTOELECTRONIC SEMICONDUCTOR DEVICE

(71) Applicant: Unikorn Semiconductor Corporation, Hsinchu (TW)

(72) Inventors: Ching-En Huang, Hsinchu (TW); Hao-Ming Ku, Hsinchu (TW); Shih-I Chen, Hsinchu (TW); Tzu-Ling Yang, Hsinchu (TW); Ya-Wen Lin, Hsinchu (TW); Chuang-Sheng Lin, Hsinchu (TW); Yi-Chia Ho, Hsinchu (TW)

(21) Appl. No.: 18/352,940

(22) Filed: Jul. 14, 2023

(30) Foreign Application Priority Data
Jul. 14, 2022 (TW) 111126477

(51) Int. Cl. H01L 33/62; H01L 25/075; H01L 33/38

(52) U.S. Cl. CPC H01L 33/62; H01L 25/0753; H01L 33/38

(57) ABSTRACT

An optoelectronic semiconductor device is provided. The optoelectronic semiconductor device includes an epitaxial stack, a trench, a concave portion, a first contact structure, and a first electrode. The epitaxial stack includes a first semiconductor structure, an active structure on the first semiconductor structure, and a second semiconductor structure on the active structure, wherein the epitaxial stack has a first portion and a second portion, and the second semiconductor structure of the first portion is separated from the second semiconductor structure of the second portion. The trench is located between the first portion and the second portion. The concave portion is located in the first portion. The first contact structure is located in the concave portion. The first electrode covers the first contact structure. When the optoelectronic semiconductor device is operating, the first portion does not emit light.

### CROSS REFERENCE TO RELATED APPLICATIONS

This application claims priority of Taiwan Patent Application No. 111126477, filed on Jul. 14, 2022, and the content of the entirety of which is incorporated by reference herein.

### BACKGROUND OF THE DISCLOSURE

### Field of the Disclosure

The present disclosure relates to a semiconductor device, and, in particular, to an optoelectronic semiconductor device.

### Description of the Related Art

Semiconductor devices are widely used. Research and development is continuously being carried out into materials related to semiconductor devices. For example, III-V group semiconductor materials including a Group III element and a Group V element may be applied to various optoelectronic semiconductor devices, such as light-emitting chips (for example, light-emitting diodes or laser diodes), light-absorbing chips (for example, photodetectors or solar cells), or non-luminous chips (for example, power components of switches or rectifiers). These optoelectronic semiconductor devices may be used in lighting, medical treatment, display, communication, sensing, power supply systems, and other fields.

Advancements in technology have allowed these optoelectronic semiconductor devices to be miniaturized. In recent years, light-emitting diodes (LEDs) composed of III-V compound have gradually gained attention in the market for applications in displays. Compared with organic light-emitting diode (OLED) displays, these light-emitting diode displays are more power-saving, more reliable, have a longer service life, and exhibit better contrast performance. Moreover, they are visible under sunlight. With the development of technology, there are still many development needs for optoelectronic semiconductor devices. Although existing optoelectronic semiconductor devices generally meet various requirements, they are not satisfactory in all respects, and further improvements are still needed.

### BRIEF SUMMARY OF THE DISCLOSURE

An embodiment of the present disclosure provides an optoelectronic semiconductor device. The optoelectronic semiconductor device includes an epitaxial stack, a trench, a concave portion, a first contact structure, and a first electrode. The epitaxial stack includes a first semiconductor structure, an active structure on the first semiconductor structure, and a second semiconductor structure on the active structure, wherein the epitaxial stack has a first portion and a second portion, and the second semiconductor structure of the first portion is separated from the second semiconductor structure of the second portion. The trench is located between the first portion and the second portion. The concave portion is located in the first portion. The first contact structure is located in the concave portion. The first electrode covers the first contact structure. When the optoelectronic semiconductor device is operating, the first portion does not emit light.

### BRIEF DESCRIPTION OF THE DRAWINGS

Embodiments of the present disclosure can be best understood from the following detailed description in conjunction with the accompanying drawings. It should be noted that, in accordance with the standard practice in the industry, various features are not drawn to scale and are used for illustration. In fact, the dimensions of the various elements may be arbitrarily expanded or reduced to clearly represent the features of the embodiments of the present disclosure.

FIG. 1A is a top view of an optoelectronic semiconductor device according to an embodiment of the present disclosure.

FIG. 1B is a cross-sectional view along line A-A′ in FIG. 1A according to an embodiment of the present disclosure.

FIG. 1C is a cross-sectional view along line B-B′ in FIG. 1A according to an embodiment of the present disclosure.

FIG. 2A is a top view of an optoelectronic semiconductor device according to another embodiment of the present disclosure.

FIG. 2B is a cross-sectional view along line A-A′ in FIG. 2A according to another embodiment of the present disclosure.

FIG. 3A is a top view of an optoelectronic semiconductor device according to yet another embodiment of the present disclosure.

FIG. 3B is a cross-sectional view along line A-A′ in FIG. 3A according to yet another embodiment of the present disclosure.

FIG. 4A is a top view of an optoelectronic semiconductor device according to yet another embodiment of the present disclosure.

FIG. 4B is a cross-sectional view along line A-A′ in FIG. 4A according to yet another embodiment of the present disclosure.

### DETAILED DESCRIPTION OF THE DISCLOSURE

The following description provides a number of embodiments or examples, for implementing various elements of the provided subject matter. Each element and its configuration of the specific examples of is described below to simplify the description of the embodiments of the present disclosure. Of course, these are only used as examples rather than limitations of the present disclosure. For example, if the description mentions that a first element is formed on a second element, it may include an embodiment in which the first element and the second element are in direct contact, or may include an embodiment in which an additional element formed between the first element and the second element, so that the first element and the second element are not in direct contact. In addition, the embodiments of the present disclosure may use repeated reference numerals in various examples. This repetition is for the purpose of brevity and clarity and not to show the relationship between the discussed different embodiments and/or configurations.

Furthermore, spatially relative terms may be used herein, such as “below”, “under”, “lower”, “above”, “on”, and the like to describe the relationship between one element or component and another element or component as shown in the drawings. These spatially relative terms are intended to encompass different orientations of the device in use or operation in addition to the orientation depicted in the drawings. For example, if the device in the drawings is turned upside down, an element described as “lower” or “below” another element or component would then be oriented “above” the other element or component. Thus, the exemplary term “below” can have both an orientation of “above” and “below”. When the device is rotated to another orientation (rotated 90° or otherwise), the spatially relative terms used herein can also be read in terms of the rotated orientation accordingly.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

The composition, the dopant and the defect of each layer of the semiconductor device in the present disclosure may be analyzed by any suitable method, for example, a secondary ion mass spectrometer (SIMS), a transmission electron microscopy (TEM), or a scanning electron microscopy (SEM). The thickness of each layer may also be analyzed by any suitable method, for example, the transmission electron microscopy (TEM) or the scanning electron microscopy (SEM).

In the application of light-emitting diodes, for example, the light-emitting diodes may be separated from the substrate by a laser-liftoff (LLO) or other separation processes, and then the light-emitting diodes may be transferred by a transferring process (for example, a mass transfer process) to an external circuit substrate. Since the transferring process needs a force to be applied to the light-emitting diode, if the mechanical strength of the light-emitting diode is insufficient, it can cause damage like a crack or breakage to an epitaxial structure. In addition, light-emitting diodes are incorporated in end products (for example, display panels) and the luminous efficiencies of the light-emitting diodes may be changed under different operating current densities. For example, when the operating current density of the light-emitting diode increases, the corresponding luminous efficiency is also increased. However, when the luminous efficiency increases to a certain value with the increase of the operating current density, the luminous efficiency may begin to decrease due to factors such as the thermal effect of the element. Therefore, when designing a light-emitting diode, it is also necessary to consider its tolerable and suitable range of the operating current density.

According to some embodiments of the present disclosure, by providing an epitaxial supporting structure that does not participate in electrical conduction, does not participate in light emission, or is not an electron-hole recombination region, the current density of optoelectronic semiconductor devices may be increased and the luminous efficiency may be enhanced. In addition, the mechanical strength of the optoelectronic semiconductor device may be increased to withstand the force applied on the element during the transferring process or other processes and avoid structural damage or breakage. Thus, the efficiency and manufacturing yield of optoelectronic semiconductor devices may be improved. Also, for example, the surface defect effect caused by the miniaturization of component size may be reduced.

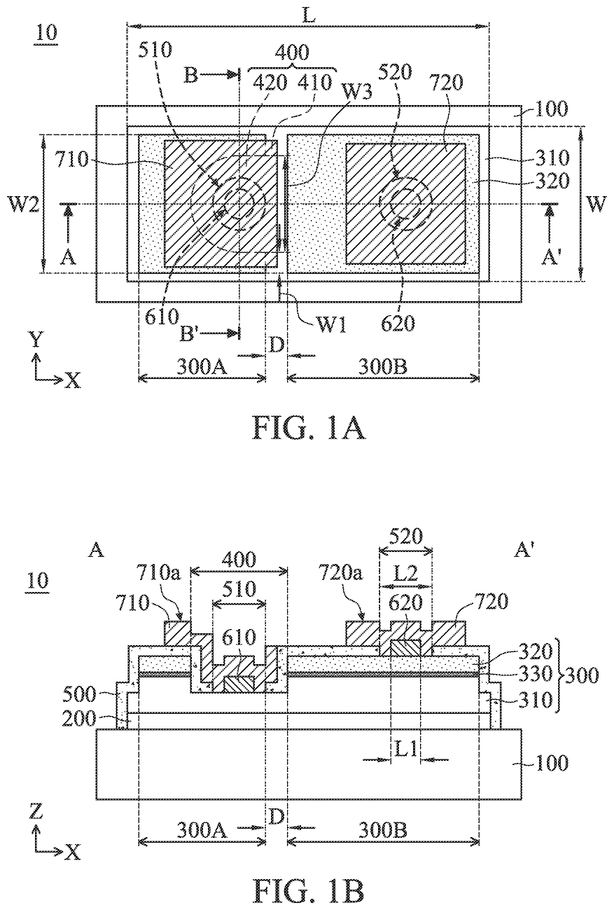

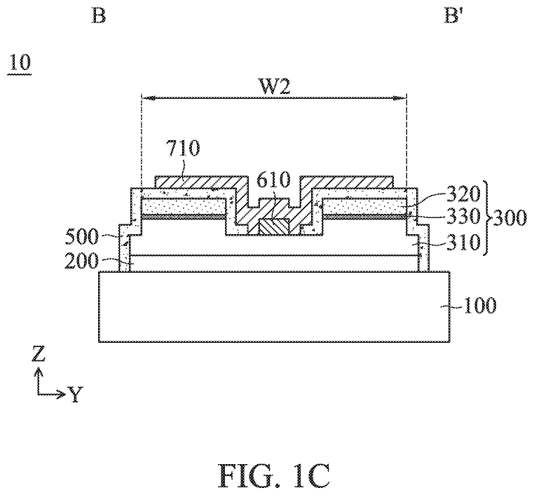

Referring to FIGS. 1A to 1C together, FIG. 1A is a top view of an optoelectronic semiconductor device 10 according to an embodiment of the present disclosure, FIG. 1B is a cross-sectional view of the optoelectronic semiconductor device 10 along line A-A′ in FIG. 1A, and FIG. 1C is a cross-sectional view of the optoelectronic semiconductor device 10 along line B-B′ in FIG. 1A. In the present embodiment, the optoelectronic semiconductor device 10 includes a base 100 and an epitaxial stack 300. As shown in FIG. 1B and FIG. 1C, the epitaxial stack 300 is located on the base 100. The optoelectronic semiconductor device 10 may further include an adhesive layer 200 located between the epitaxial stack 300 and the base 100. In other words, the epitaxial stack 300 and the base 100 are bonded to each other by the adhesive layer 200.

It should be understood that, according to some embodiments, when forming the optoelectronic semiconductor device 10 as shown in FIG. 1A to FIG. 1C, the epitaxial stack 300 is formed on an additional growth substrate (not shown) by, for example, a metal-organic chemical vapor deposition (MOCVD), a hydride vapor phase epitaxy (HVPE), a molecular beam epitaxy (MBE), a liquid-phase epitaxy (LPE), a vapor phase epitaxy (VPE), or other suitable epitaxy growth processes. Next, the growth substrate is inverted and the epitaxial stack is bonded on the base 100 by the adhesive layer 200, and then the growth substrate is removed. Therefore, in various embodiments of the present disclosure, the upper and lower order of elements in various schematic diagrams does not represent the actual formation order thereof. In other embodiments, the base 100 may be a growth substrate, and the epitaxial stack 300 is directly epitaxially grown on the base 100.

In some embodiments, as shown in FIG. 1B and FIG. 1C, the epitaxial stack 300 includes a first semiconductor structure 310, a second semiconductor structure 320, and an active structure 330. The second semiconductor structure 320 is located on the first semiconductor structure 310, and the active structure 330 is located between the first semiconductor structure 310 and the second semiconductor structure 320. The epitaxial stack 300 has a first portion 300A and a second portion 300B, wherein the first semiconductor structure 310 of the first portion 300A is connected to the first semiconductor structure 310 of the second portion 300B. When viewed in a top view, as shown in FIG. 1A, the second semiconductor structure 320 of the first portion 300A is separated from the second semiconductor structure 320 of the second portion 300B, and the trench 410 is located between the first portion 300A and the second portion 300B. In other words, the trench 410 separates the second semiconductor structure 320 of the first portion 300A from the second semiconductor structure 320 of the second portion 300B with a distance D. Wherein, the distance D is, for example, 0.1 μm to 30 μm, or 1 μm to 10 μm in another embodiment. In some embodiments, when the distance D is less than 1 μm, the stability of the process is not easy to control, which may easily lead to device failure. In some embodiments, when the distance D is greater than 10 μm, the mechanical strength of the device may be insufficient when the light-emitting diode is transferred to the external circuit substrate, which may easily lead to problems such as cracks or breakages of the epitaxial stack 300.

As shown in FIG. 1B, the active structure 330 in the first portion 300A and the active structure 330 in the second portion 300B are separated from each other. According to an embodiment, the active structure 330 of the second portion 300B may emit light. Specifically, under this structural design, when the optoelectronic semiconductor device 10 is operating, only the active structure 330 of the second portion 300B is an electron-hole recombination region. Therefore, the active structure 330 of the second portion 300B may emit light and the second portion 300B act as a light-emitting structure. Since the active structure 330 of the first portion 300A does not participate in electrical conduction and/or light emission, or is not an electron-hole recombination region for light-emitting, the first portion 300A may be used as a supporting structure to increase current density and enhance luminous efficiency. Even if the base 100 needs to be removed and the optoelectronic semiconductor device 10 may be transferred in subsequent processes, the optoelectronic semiconductor device 10 still has sufficient mechanical strength to prevent the epitaxial stack 300 from being damaged or broken, thereby improving the yield.

The epitaxial stack 300 may have a concave portion 420. As shown in FIG. 1A, the concave portion 420 is located in the first portion 300A. In one embodiment, the concave portion 420 is located on the side of the first portion 300A that is closer to the trench 410 and the concave portion 420 communicates with the trench 410. That is, the concave portion 420 is located on the side of the first portion 300A which is close to the second portion 300B. As shown in FIG. 1A, the concave portion 420 recesses from the side close to the trench 410 to the side away from the trench 410 by etching. The concave portion 420 may have a gradually changing width (for example, the third width W3) that the third width W3 may gradually decrease from the side close to the trench 410 to the side away from the trench 410. As shown in FIG. 1A, the side of the second semiconductor structure 320 of the first portion 300A that is close to the trench 410 may have a first width W1, the side of the second semiconductor structure 320 of the first portion 300A that is away from the trench 410 may have a second width W2, which is greater than the first width W1. In some embodiments, the side of the second semiconductor structure 320 of the first portion 300A that is close to the concave portion 420 has a first width W1, the side of the second semiconductor structure 320 of the first portion 300A that is farther away from the concave portion 420 has a second width W2, which is greater than the first width W1. The side of the concave portion 420 that is close to the trench 410 has a third width W3, and the third width W3 is smaller than the second width W2. In one embodiment, the concave portion 420 recesses from the trench 410 toward a direction away from the second portion 300B. Hereinafter, the trench 410 and the concave portion 420 are collectively referred to as a “recess” 400.

As shown in FIGS. 1A to 1C, the optoelectronic semiconductor device 10 may further include an insulating layer 500, a first contact structure 610, a second contact structure 620, a first electrode 710, and a second electrode 720. The insulating layer 500 is located on the epitaxial stack 300 and has a first opening 510 and a second opening 520. The first opening 510 is located on the first portion 300A, and the second opening 520 is located on the second portion 300B. As shown in FIG. 1A, in the present embodiment, the first opening 510 is located in the concave portion 420. The first contact structure 610 and the second contact structure 620 are on the epitaxial stack 300 and located in the first opening 510 and the second opening 520, respectively. The first electrode 710 is located on the first contact structure 610 and covers the first contact structure 610, a portion of the insulating layer 500, and a portion of the trench 410. The second electrode 720 is located on the second contact structure 620 and covers the second contact structure 620 and a portion of the insulating layer 500. In the present embodiment, the first contact structure 610 and the second contact structure 620 are both separated from the insulating layer 500 with a distance. That is, neither the first contact structure 610 nor the second contact structure 620 are in direct contact with the insulating layer 500. In another embodiment, the first contact structure 610 and/or the second contact structure 620 may directly contact with the insulating layer 500. In some embodiments, the second contact structure 620 covers the second semiconductor structure 320 of the second portion 300B. The first contact structure 610 and the second contact structure 620 may reduce the internal resistance of the optoelectronic semiconductor device 10 and facilitate the conduction of current. In the present embodiment, a projection area of the portion of the second contact structure 620 covering the second semiconductor structure 320 on the base 100 is smaller than a projection area of the second electrode 720 on the base 100. In another embodiment, the projection area of the portion of the second contact structure 620 covering the second semiconductor structure 320 on the base 100 is greater than or equal to the projection area of the second electrode 720 on the base 100. Therefore, the current density of the light-emitting element may be adjusted by controlling the area of the second contact structure 620 covering the second semiconductor structure 320 of the second portion 300B, so as to achieve the performance of the optimized operating current density of the device.

In some embodiments, the base 100 may be silicon (Si), sapphire, glass, ceramic, aluminum nitride (AlN), epoxy resin, quartz, or acrylic resin. In one embodiment, the base 100 is a sapphire substrate. In addition, the shape of the base 100 is, for example, a circle, a square, a rectangle, a rhombus, or other polygons. Herein, the base 100 is a rectangle as an example, but its shape is not intended to limit the present disclosure.

The aforementioned optoelectronic semiconductor device 10 may be a light-emitting diode (LED) and have a length L and a width W in a top view shown in FIG. 1A. In other words, the base 100 has the length L and the width W. The aforementioned length L is not greater than 150 microns, or 20 microns to 150 microns, 20 microns to 60 microns, or 60 microns to 150 microns in other embodiments. The aforementioned width W is not greater than 100 microns, for example, 3 microns to 75 microns, 3 microns to 10 microns, 10 microns to 30 microns, or 30 microns to 75 microns.

In some embodiments, when viewing from a top view, the first semiconductor structure 310 has a first top view area A1 (that is, the length L×the width W), for example, less than 3000 μm². In other words, when viewing from the top view, the optoelectronic semiconductor device 10 has the first top view area A1. The second portion 300B has a second top view area A2, and the first portion 300A has a third top view area A3. The second top view area A2 may be 3% to 90% of the first top view area A1, for example, 30% to 80%. According to some embodiments, when the second top view area A2 is less than 3% of the first top view area A1, the requirements of the product performance cannot be accomplished. According to some embodiments, when the second top view area A2 is greater than 90% of the first top view area A1, the component performance is decreased. The third top view area A3 may be 1% to 70% of the first top view area A1, for example, 5% to 50%. According to some embodiments, when the third top view area A3 is less than 1% of the first top view area A1, there may be problems of difficulty in manufacturing components and lower performance. According to some embodiments, when the third top view area A3 is greater than 70% of the first top view area A1, the requirements of the product performance cannot be accomplished. In addition, when viewed in the top view, the second portion 300B has a perimeter P, and the ratio of the perimeter P of the second portion 300B to the second top view area A2 is 0.05 to 0.6 (unit: μm⁻¹), for example, 0.1 to 0.5. According to some embodiments, when the ratio of the perimeter P to the second top view area A2 is less than 0.05, it is difficult to miniaturize the device. According to some embodiments, when the ratio of the perimeter P to the second top view area A2 is greater than 0.6, the device performance may be affected due to the greater side wall damage, thereby affecting the luminous efficiency of the device.

In the embodiment of the present disclosure, the material of the adhesive layer 200 may be an organic adhesive material, an inorganic adhesive material, a light-transmitting material, or a combination thereof. The aforementioned organic adhesive material includes benzocyclobutene (BCB) or polyimide (PI). The aforementioned inorganic adhesive material includes silicon oxide (SiO₂), titanium oxide (TiO₂), tantalum oxide (Ta₂O₅), aluminum oxide (Al₂O₃), or silicon nitride (SiNₓ). The aforementioned light-transmitting material includes transparent conductive material, for example, indium tin oxide (ITO). The aforementioned adhesive layer 200 may be formed by a spin coating process and a heating process.

In some embodiments, the first semiconductor structure 310 and the second semiconductor structure 320 may be doped by in-situ doping during the epitaxial growth process and/or by implanting with dopants after the epitaxial growth process. The first semiconductor structure 310 may include a first dopant to have a first conductivity type, and the second semiconductor structure 320 may include a second dopant to have a second conductivity type. The first semiconductor structure 310 and the second semiconductor structure 320 have different conductivity types, that is, the first conductivity type is different from the second conductivity type. The first conductivity type is, for example, p-type and the second conductivity type is, for example, n-type to provide holes and electrons, respectively. Alternatively, the first conductivity type is, for example, n-type and the second conductivity type is, for example, p-type to provide electrons or holes, respectively. In one embodiment, the first dopant or the second dopant may be magnesium (Mg), zinc (Zn), silicon (Si), carbon (C) or tellurium (Te).

In some embodiments of the present disclosure, the first semiconductor structure 310, the second semiconductor structure 320, and the active structure 330 may include III-V group semiconductor elements, for example, may include aluminum (Al), gallium (Ga), arsenic (As), phosphorus (P), indium (In), or nitrogen (N). Specifically, in some embodiments of the present disclosure, the aforementioned III-V group semiconductor material may be binary compound semiconductor (such as, GaAs, GaP, GaN, or InP), ternary compound semiconductor (such as, InGaAs, AlGaAs, GaInP, AlInP, InGaN, or AlGaN), or quaternary compound semiconductor (such as, AlGaInAs, AlGaInP, AlInGaN, InGaAsP, InGaAsN, or AlGaAsP).

In some embodiments of the present disclosure, when the optoelectronic semiconductor device 10 is a light-emitting device, the active structure 330 can emit light while the optoelectronic semiconductor device 10 is operating. The light emitted by the active structure 330 includes visible light or invisible light. The wavelength of the light emitted by the optoelectronic semiconductor device 10 depends on the composition of the material of the active structure 330. For example, when the material of the active structure 330 includes InGaN-based material, the active structure 330 can emit blue light or deep blue light with a peak wavelength of 400 nm to 490 nm, or the active structure 330 can emit green light with a peak wavelength of 490 nm to 550 nm. When the material of the active structure 330 includes AlGaN-based material, the active structure 330 can emit ultraviolet light with a peak wavelength of 250 nm to 400 nm. When the material of the active structure 330 includes InGaAs-based material, InGaAsP-based material, AlGaAs-based material, or AlGaInAs-based material, the active structure 330 can emit infrared light with a peak wavelength of 700 nm to 1700 nm. When the material of the active structure 330 includes InGaP-based material or AlGaInP-based material, the active structure 330 can emit red light with a peak wavelength of 610 nm to 700 nm, or the active structure 330 can emit yellow light with a wavelength of 530 nm to 600 nm. Preferably, the active structure 330 emits infrared light with a peak wavelength of 700 nm to 1700 nm or emits red light with a peak wavelength of 610 nm to 700 nm.

As mentioned above, according to some embodiments, the epitaxial stack 300 and the adhesive layer 200 are formed on another growth substrate (not shown), and then inverted and bonded to the base 100. In other words, the second semiconductor structure 320, the active structure 330, the first semiconductor structure 310, and the adhesive layer 200 are sequentially formed on the growth substrate, and then the base 100 and the epitaxial stack 300 are bonded by the adhesive layer 200, and then the growth substrate is removed.

According to some embodiments, the trench 410 and the concave portion 420 may be formed by removing a portion of the epitaxial stack 300 by the first etching process, so that a portion of the first semiconductor structure 310 is exposed. Then, a portion of the first semiconductor structure 310 is further removed by the second etching process, so as to form a plurality of optoelectronic semiconductor devices 10 which are adjacent to and spaced apart from each other and a portion of the base 100 may be exposed. The aforementioned first etching process and second etching process may be, for example, a dry etching process, a wet etching process, or a combination thereof. For example, the dry etching process may include plasma etching (PE), reactive ion etching (RIE), inductively coupled plasma reactive ion etching (ICP-RIE). The wet etching process may use acidic solution or alkaline solution. In detail, the aforementioned first etching process may form the trench 410 and the concave portion 420, and define the epitaxial stack 300 as the first portion 300A and the second portion 300B, wherein the second semiconductor structure 320 (or the active structure 330) of the first portion 300A is separated from the second semiconductor structure 320 (or the active structure 330) of the second portion 300B by the trench 410, and a portion of the first semiconductor structure 310 is exposed at the trench 410 and the concave portion 420.

Continuing to refer to FIG. 1B, the insulating layer 500 may cover the epitaxial stack 300 to protect the epitaxial stack 300. In some embodiments, the insulating layer 500 may include an oxide insulating material, a non-oxide insulating material, or a combination thereof. For example, the oxide insulating material may include silicon oxide (SiO₂), titanium oxide (TiO₂), tantalum oxide (Ta₂O₅). The non-oxide insulating material may include silicon nitride (SiNₓ), benzocyclobutene (BCB), cycloolefin polymer (COC), fluorocarbon polymer, calcium fluoride (CaF₂), or magnesium fluoride (MgF₂). In other embodiments, the insulating layer 500 may include a distributed Bragg reflector structure (DBR), so that the light is directed toward the base 100. The distributed Bragg reflector structure is formed by alternately stacking two or more insulating materials with different refractive indices. For example, the distributed Bragg reflector structure is formed by alternately stacking SiO₂/TiO₂ or SiO₂/Ta₂O₅.

Continuing to refer to FIG. 1B, the first contact structure 610 is in direct contact with and electrically connected to the first semiconductor structure 310. The second contact structure 620 is in direct contact with and electrically connected to the second semiconductor structure 320. In the present embodiment, the area of the projection of the first opening 510 on the base 100 (or on the first semiconductor structure 310) may overlap with the area of the projection of the first contact structure 610 on the base 100 (or on the first semiconductor structure 310), and the area of the projection of the second opening 520 on the base 100 (or on the first semiconductor structure 310) may overlap with the area of the projection of the second contact structure 620 on the base 100 (or on the first semiconductor structure 310). As shown in FIG. 1B, the second contact structure 620 has a first length L1, and the second opening 520 has a second length L2. In some embodiments, the second length L2 is greater than the first length L1, so that the second semiconductor structure 320 is exposed from the second opening 520. In other embodiments, the second length L2 may be less than or equal to the first length L1, such that the second semiconductor structure 320 is not exposed from the second opening 520.

In some embodiments of the present disclosure, the first contact structure 610 and the second contact structure 620 may each include a metal material, an alloy material, a conductive oxide material, and the like. The metal material is, for example, chromium (Cr), titanium (Ti), germanium (Ge), beryllium (Be), zinc (Zn), gold (Au), silver (Ag), tin (Sn), nickel (Ni), copper (Cu), and the like. The alloy material may include alloys of at least two of the aforementioned metals, for example, germanium-gold-nickel (GeAuNi), beryllium-gold (BeAu), germanium-gold (GeAu), zinc-gold (ZnAu), gold-tin (AuSn), tin-silver-copper (SnAgCu), and the like. The conductive oxide material may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO), and the like. In one embodiment, the first contact structure 610 and the second contact structure 620 are GeAu alloy and BeAu alloy, respectively.

The first opening 510 and the second opening 520 may have the same or different shapes, and the first contact structure 610 and the second contact structure 620 may also have the same or different shapes, for example, circular, rectangular or other polygonal shapes. The shape of the first opening 510 and the shape of the first contact structure 610 may be the same or different, and/or the shape of the second opening 520 and the shape of the second contact structure 620 may be the same or different. That is, the shape of the first opening 510 and the shape of the first contact structure 610 may be set conformally, and the shape of the second opening 520 and the shape of the second contact structure 620 may be set conformally.

According to some embodiments, in the manufacturing process of the optoelectronic semiconductor device 10, after the first contact structure 610 is formed, the first heat treatment process of 450° C. to 600° C. may be performed, so that an ohmic contact is formed between the first contact structure 610 and the first semiconductor structures 310. After the second contact structure 620 is formed, the second heat treatment process of 450° C. to 600° C. may be performed, so that an ohmic contact is formed between the second contact structure 620 and the second semiconductor structure 320. In some embodiments, the first heat treatment process and the second heat treatment process may be the same process. In other embodiments, the first heat treatment process and the second heat treatment process are different processes, and the temperature of the first heat treatment process may be higher than the temperature of the second heat treatment process.

Continuing to refer to FIG. 1B, the first electrode 710 is located on the insulating layer 500 and the first contact structure 610 and is electrically connected to the first semiconductor structure 310 by the first contact structure 610. The second electrode 720 is located on the insulating layer 500 and the second contact structure 620 and is electrically connected to the second semiconductor structure 320 by the second contact structure 620. In the present embodiment, the first electrode 710 overlaps with the first portion 300A in the vertical direction (for example, the Z direction shown in FIG. 1B), but does not overlap with the second portion 300B. The second electrode 720 overlaps with the second portion 300B in the vertical direction but does not overlap with the first portion 300A. The first top surface 710a of the first electrode 710 on the second semiconductor structure 320 of the first portion 300A and the second top surface 720a of the second electrode 720 on the second semiconductor structure 320 of the second portion 300B may be substantially coplanar. The first electrode 710 and the second electrode 720 may electrically connect the optoelectronic semiconductor device 10 with an external power source. The current may be conducted in the optoelectronic semiconductor device 10 by the first electrode 710 and the second electrode 720, and the current may drive the carriers in the epitaxial stack 300 to be recombined and emit light. The light may be emitted towards the base 100 or away from the base 100.

In some embodiments of the present disclosure, the materials of the first electrode 710 and the second electrode 720 may be the same or different, and each may include a metal oxide material, a metal, or an alloy. The metal oxide material includes indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO), or the like. The metal is, for example, germanium (Ge), beryllium (Be), zinc (Zn), gold (Au), platinum (Pt), titanium (Ti), aluminum (Al), nickel (Ni), tin (Sn), indium (In), copper (Cu), or the like. The alloy may include at least two metal selected from the group consisting of the aforementioned metals, for example, gold-tin (AuSn), tin-silver-copper (SnAgCu), germanium-gold-nickel (GeAuNi), beryllium-gold (BeAu), germanium-gold (GeAu), zinc-gold (ZnAu), or other alloys including tin (Sn) elements.

In some embodiments, the first electrode 710 and the second electrode 720 may be formed by a deposition process, and it will not be repeated here. In addition, a planarization process, for example, a chemical mechanical planarization (CMP) process, may be performed, so that the first top surface 710a of the first electrode 710 and the second top surface 720a of the second electrode 720 may substantially coplanar. Therefore, a flat surface is provided, so that the first electrode 710 and the second electrode 720 may be connected to external circuits at the same level, thereby improving the yield and reliability of the optoelectronic device 10. According to some embodiments, a metal material layer may be further included, and the metal material layer is formed on the first contact structure 610 in the concave portion 420 (not shown). The aforementioned metal material layer is, for example, between the first electrode 710 and the first contact structure 610, so that the first top surface 710a of the first electrode 710 and the second top surface 720a of the second electrode 720 are more likely to be coplanar.

According to some embodiments, the active structure 330 of the first portion 300A may not participate in electrical conduction and light emission. Alternatively, the active structure 330 of the first portion 300A may participate in electrical conduction but not participate in light emission. For example, in the embodiments shown in FIG. 1A to FIG. 1C, in the epitaxial stack 300, the shortest electric path between the region where the epitaxial stack 300 is in direct contact with the first contact structure 610 (and/or the first electrode 710) and the region where the epitaxial stack 300 is in direct contact with the second contact structure 620 (and/or the second electrode 720) does not pass through the active structure 330 of the first portion 300A. In the present structural design, when the semiconductor device 10 is operating, the active structure 330 of the first portion 300A does not participate in electrical conduction and does not participate in light emission. According to another embodiment, in the epitaxial stack 300, the shortest electric path between the region where the epitaxial stack 300 is in direct contact with the first contact structure 610 (and/or the first electrode 710) and the region where the epitaxial stack 300 is in direct contact with the second contact structure 620 (and/or the second electrode 720) passes through the active structure 330 of the first portion 300A. In that case, the first contact structure 610 and/or the first electrode 710 is disposed to be in direct contact with the active structure 330 or the second semiconductor structure 320 of the first portion 300A. In the present structural design, when the semiconductor device 10 is operating, the active structure 330 of the first portion 300A participates in electrical conduction and does not participate in light emission.

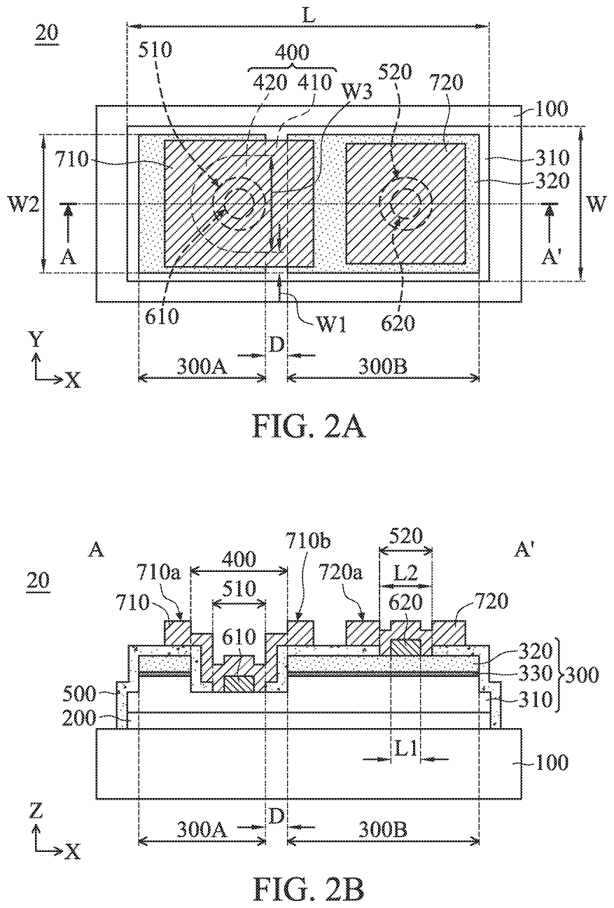

FIG. 2A is a top view of an optoelectronic semiconductor device 20 according to yet another embodiment of the present disclosure. FIG. 2B is a cross-sectional view of the optoelectronic semiconductor device 20 along the line A-A′ in FIG. 2A. The optoelectronic semiconductor device 20 has a structure similar to the structure of the optoelectronic semiconductor device 10 (FIG. 1A to FIG. 1C), and the difference between the optoelectronic semiconductor device 20 and the optoelectronic semiconductor device 10 is that the first electrode 710 of the optoelectronic semiconductor device 20 overlaps with a portion of the second portion 300B in the vertical direction (Z direction as shown in FIG. 2B). Specifically, in the present embodiment, since the first electrode 710 covers the concave portion 420 and the trench 410 and extends to cover a portion of the second portion 300B, the epitaxial stack 300 in the optoelectronic semiconductor device 20 may have the improved mechanical strength and supporting force than the epitaxial stack 300 in the optoelectronic semiconductor device 10. In addition, the overlapping portion of the first electrode 710 and the second portion 300B in the vertical direction (Z direction) has a third top surface 710b, and the first top surface 710a, the second top surface 720a, and the third top surface 710b are substantially coplanar. Therefore, in the subsequent process, the first electrode 710 and the second electrode 720 may be connected to external circuits at the same level, thereby being beneficial to improve yield and reliability.

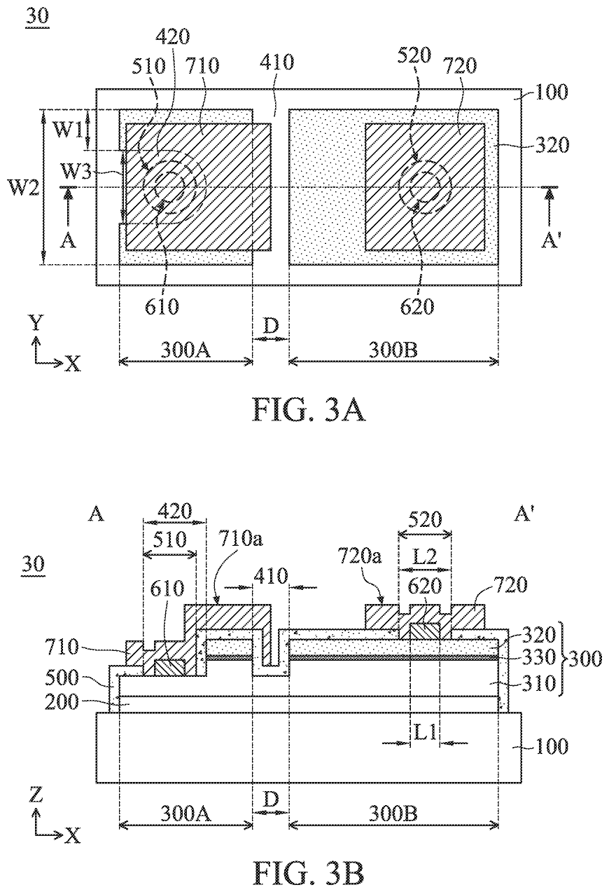

FIG. 3A is a top view of an optoelectronic semiconductor device 30 according to yet another embodiment of the present disclosure. FIG. 3B is a cross-sectional view of the optoelectronic semiconductor device 30 along line A-A′ in FIG. 3A. The optoelectronic semiconductor device 30 has a structure similar to the structure of the optoelectronic semiconductor device 10 (FIG. 1A to FIG. 1C), and the difference between the optoelectronic semiconductor device 30 and the optoelectronic semiconductor device 10 is the location of the concave portion 420.

As shown in FIG. 3A and FIG. 3B, in the present embodiment, the concave portion 420 is located on the side of the first portion 300A away from the trench 410, and is not connected to the trench 410. The width of the concave portion 420 gradually decreases from the side away from the trench 410 to the side close to the trench 410. The concave portion 420 recesses from the side of the first portion 300A away from the trench 410 toward the second portion 300B. In the present embodiment, the first electrode 710 covers the trench 410.

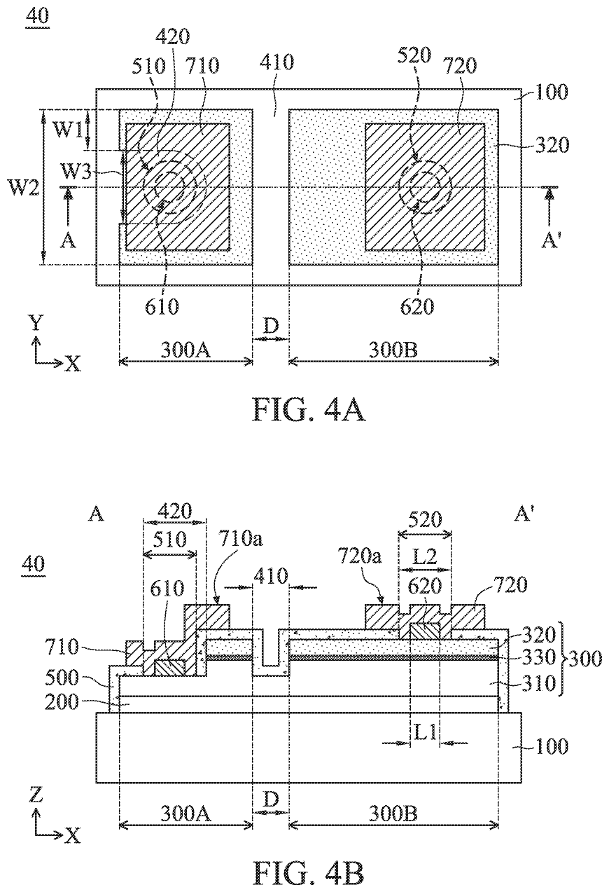

FIG. 4A is a top view of an optoelectronic semiconductor device 40 according to yet another embodiment of the present disclosure. FIG. 4B is a cross-sectional view of the optoelectronic semiconductor device 40 along line A-A′ in FIG. 4A. The optoelectronic semiconductor device 40 has a structure similar to the structure of the optoelectronic semiconductor device 30 (FIG. 3A and FIG. 3B), and the different between the optoelectronic semiconductor device 40 and the optoelectronic semiconductor device 30 is that the first electrode 710 of the optoelectronic semiconductor device 40 does not cover the trench 410. Specially, the first electrode 710 is formed on the concave portion 420 and a portion of the insulating layer 500 and does not extend beyond the first portion 300A. In the present embodiment, there is a space between the first electrode 710 and the trench 410. In another embodiment, the first electrode 710 is immediately adjacent to the trench 410.

In summary, the optoelectronic semiconductor device disclosed in the present disclosure provides an epitaxial supporting structure that does not participate in electrical conduction and/or light emission, or is not an electron-hole recombination region, thereby increasing the current density of the optoelectronic semiconductor device and improving the luminous efficiency. In addition, the mechanical strength of the optoelectronic semiconductor device may be increased to withstand the force applied on the element during transferring process or other processes, avoiding structural damage or breakage, thereby enhancing the efficiency and manufacturing yield of the optoelectronic semiconductor device, and improving, for example, the surface defect effect caused by the miniaturization of component size.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An optoelectronic semiconductor device, comprising:
an epitaxial stack comprising a first semiconductor structure, an active structure on the first semiconductor structure, and a second semiconductor structure on the active structure, wherein the epitaxial stack has a first portion and a second portion, and the second semiconductor structure of the first portion is separated from the second semiconductor structure of the second portion;
a trench located between the first portion and the second portion;
a concave portion located in the first portion;
a first contact structure located in the concave portion; and
a first electrode covering the first contact structure,
wherein when the optoelectronic semiconductor device is operating, the first portion does not emit light.

2. The optoelectronic semiconductor device as claimed in claim 1, wherein the concave portion communicates with the trench.

3. The optoelectronic semiconductor device as claimed in claim 1, wherein when viewed in a top view, the optoelectronic semiconductor device has a first area, the second portion has a second area, and the second area is 3% to 90% of the first area.

4. The optoelectronic semiconductor device as claimed in claim 3, wherein when viewed in the top view, the first portion has a third area, and the third area is 1% to 70% of the first area.

5. The optoelectronic semiconductor device as claimed in claim 3, wherein when viewed in the top view, the second portion has a perimeter, and a ratio of the perimeter to the second area is 0.05 to 0.6.

6. The optoelectronic semiconductor device as claimed in claim 1, wherein the first electrode overlaps the first portion in a vertical direction.

7. The optoelectronic semiconductor device as claimed in claim 6, wherein the first electrode overlaps the second portion in the vertical direction.

8. The optoelectronic semiconductor device as claimed in claim 1, wherein the concave portion is located on a side of the first portion away from the trench.

9. The optoelectronic semiconductor device as claimed in claim 1, wherein when viewed in a top view, a side of the second semiconductor structure close to the concave portion has a first width, a side of the second semiconductor structure away from the concave portion has a second width, and the second width is greater than the first width.

10. The optoelectronic semiconductor device as claimed in claim 1, further comprising:
an insulating layer located on the epitaxial stack and not in direct contact with the first contact structure.

11. The optoelectronic semiconductor device as claimed in claim 1, further comprising:
a second contact structure located on the second portion.

12. The optoelectronic semiconductor device as claimed in claim 11, further comprising:
a second electrode located on the second contact structure and covering the second contact structure.

13. The optoelectronic semiconductor device as claimed in claim 11, further comprising:
an insulating layer located on the epitaxial stack, and having a first opening in the concave portion and a second opening in the second portion,
wherein the first contact structure is located in the first opening and the second contact structure is located in the second opening.

14. The optoelectronic semiconductor device as claimed in claim 13, wherein an area of a projection of the first opening on the first semiconductor structure overlaps with an area of a projection of the first contact structure on the first semiconductor structure.

15. The optoelectronic semiconductor device as claimed in claim 13, wherein the first contact structure is in direct contact with the active structure or the second semiconductor structure of the first portion.

16. The optoelectronic semiconductor device as claimed in claim 13, wherein the first electrode is in direct contact with the active structure or the second semiconductor structure of the first portion.

17. The optoelectronic semiconductor device as claimed in claim 1, wherein the first electrode covers the trench.

18. The optoelectronic semiconductor device as claimed in claim 1, wherein the first electrode has a distance with the trench.

19. The optoelectronic semiconductor device as claimed in claim 1, wherein the concave portion is located on a side of the first portion close to the second portion.

20. The optoelectronic semiconductor device as claimed in claim 1, wherein a distance between the second semiconductor structure of the first portion and that of the second portion is 0.1 μm to 30 μm.
